(19) United States
(12) Patent Application Publication
(10) Pub. No.: US 2016/0284745 A1
(43) Pub. Date: Sep. 29, 2016

(54) IMAGE SENSOR CHIP

(71) Applicant: SILICONFILE TECHNOLOGIES, INC., Gyeonggi-do (KR)

(72) Inventors: Jae-Young PARK, Gyeonggi-do (KR); Ho-Soo KIM, Gyeonggi-do (KR)

(21) Appl. No.: 15/022,877

(22) PCT Filed: Aug. 22, 2014
(86) PCT No.: PCT/KR2014/007847

§ 371 Date: Mar. 17, 2016

(30) Foreign Application Priority Data
Sep. 17, 2013 (KR) 10-2013-0111943

(51) Int. Cl. H01L 27/146

(52) U.S. Cl. CPC H01L 27/1462; H01L 27/14627; H01L 27/14645

(57) ABSTRACT

The present invention relates to an image sensor chip of which the efficiency such as sensitivity/quantum efficiency (QE) and the like can be improved by forming an antireflection film on a layer from which most reflection occurs in the image sensor chip, and image degradation can be additionally improved by preventing a ghost phenomenon and a flare phenomenon.

### TECHNICAL FIELD

The present invention relates to an image sensor chip, and more specifically, to an image sensor chip for improving an image degradation by preventing a ghost phenomenon and a flare phenomenon.

### BACKGROUND ART

Japanese patent publication No. 2005-284040, issued on Oct. 13, 2005, discloses a technique for forming an antireflection film, which reduces a reflection ray, on an optical side of an optical member on which a plurality of lens are arrayed.

An anti-reflective layer is used to improve an efficiency of sensitivity/quantum efficiency (QE) in an image sensor, but a light loss occurs because an amount of a light, which is reflected by a micro-lens and an optical filter, is great.

The present inventor has developed an image sensor chip of which the efficiency such as sensitivity/quantum efficiency (QE) and the like can be improved by forming an antireflection film on a layer from which most reflection occurs in the image sensor chip, and image degradation can be additionally improved by preventing a ghost phenomenon and a flare phenomenon.

### DISCLOSURE

### Technical Problem

The present invention is directed to an image sensor chip for improving sensitivity/quantum efficiency (QE) by forming an antireflection film on a layer from which most reflection occurs in the image sensor chip.

### Technical Solution

In accordance with an embodiment of the present invention, an image sensor chip may include a micro-lens configured to concentrate a light; an optical filter configured to pass a specific frequency band of the light concentrated by the micro-lens; a photo-diode configured to convert the light, which is passed through the optical filter, into an electrical signal; a semiconductor substrate in which the photodiode is moduled; an over coating layer (OCL) configured to be stacked on both sides of the optical filter and obtain a process margin of the micro-lens by reducing a process step; an insulation layer for an inter-metal dielectric; and an antireflection film configured to suppress a light reflection on a side of at least one of the photodiode, the optical filter and the micro-lens.

The antireflection film may be formed to have a multi-coating layer.

The antireflection film may include a zirconium oxide layer and two aluminium oxide layers, which are coated on both sides of the zirconium oxide layer.

The antireflection film may further include a magnesium fluoride layer, which is coated on any one of the two aluminum oxide layers.

The zirconium oxide layer may be coated with a thickness of 160 to 200 Å.

The aluminium oxide layer may be coated with a thickness of 800 to 1000 Å.

The magnesium fluoride layer may be coated with a thickness of 1000 to 1300 Å.

The image sensor chip may be front side illumination type image sensor.

The image sensor chip may be a back side illumination type image sensor.

The image sensor chip may be a 3-dimensional stack type image sensor.

### Advantageous Effects

The present invention may improve the efficiency such as sensitivity/quantum efficiency (QE) and the like by forming an antireflection film on a layer from which most reflection occurs in the image sensor chip, and additionally improve an image degradation by preventing a ghost phenomenon and a flare phenomenon.

### DESCRIPTION OF DRAWINGS

FIG. 1 is a cross sectional view illustrating an image sensor in accordance with a first embodiment of the present invention.

FIG. 2 is a cross sectional view illustrating an image sensor in accordance with a second embodiment of the present invention.

FIG. 3 is a cross sectional view illustrating an image sensor in accordance with a third embodiment of the present invention.

FIG. 4 is a cross sectional view illustrating an image sensor in accordance with a fourth embodiment of the present invention.

FIG. 5 is a cross sectional view illustrating an image sensor in accordance with a fifth embodiment of the present invention.

FIG. 6 is a cross sectional view illustrating an antireflection film of an image sensor in accordance with an embodiment of the present invention.

FIG. 7 is a graph illustrating reflectance according to a light incident angle of an image sensor chip in accordance with an embodiment of the present invention.

### BEST MODE

Hereinafter, various embodiments will be described below in more detail with reference to the accompanying drawings such that a skilled person in this art understand and implement the present invention easily.

The present invention may, however, be embodied in different forms and should not be construed as being limited to the embodiments set forth herein.

Rather, these embodiments are provided so that this disclosure will be thorough and complete. Throughout the disclosure, like reference numerals refer to like parts throughout the various figures and embodiments of the present invention.

The present invention may improve the efficiency of an image sensor chip such as sensitivity/quantum efficiency (QE) and the like can be improved by forming an antireflection film on a layer from which most reflection occurs in the image sensor chip, and may additionally prevent a ghost phenomenon and a flare phenomenon. Herein, the layer from which most reflection occurs in the image sensor chip may be a surface of a photodiode, an optical filter or a micro-lens.

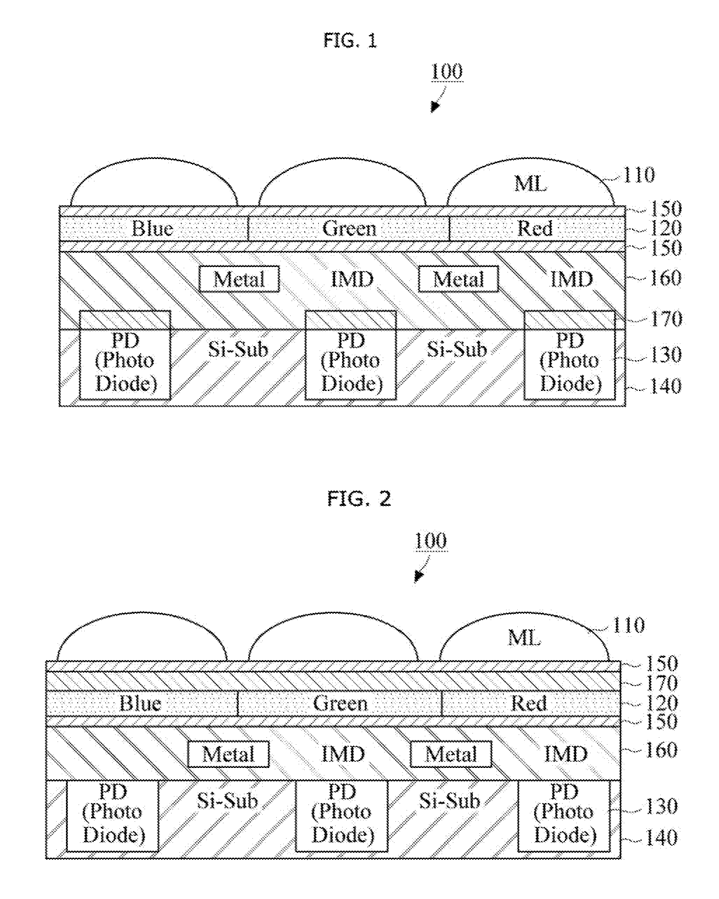

FIG. 1 is a cross sectional view illustrating an image sensor in accordance with a first embodiment of the present invention, and an antireflection film is formed on a side of a photodiode of an image sensor of a front side illumination type.

FIG. 2 is a cross sectional view illustrating an image sensor in accordance with a second embodiment of the present invention, and an antireflection film is formed on a side of an optical film of an image sensor of a front side illumination type.

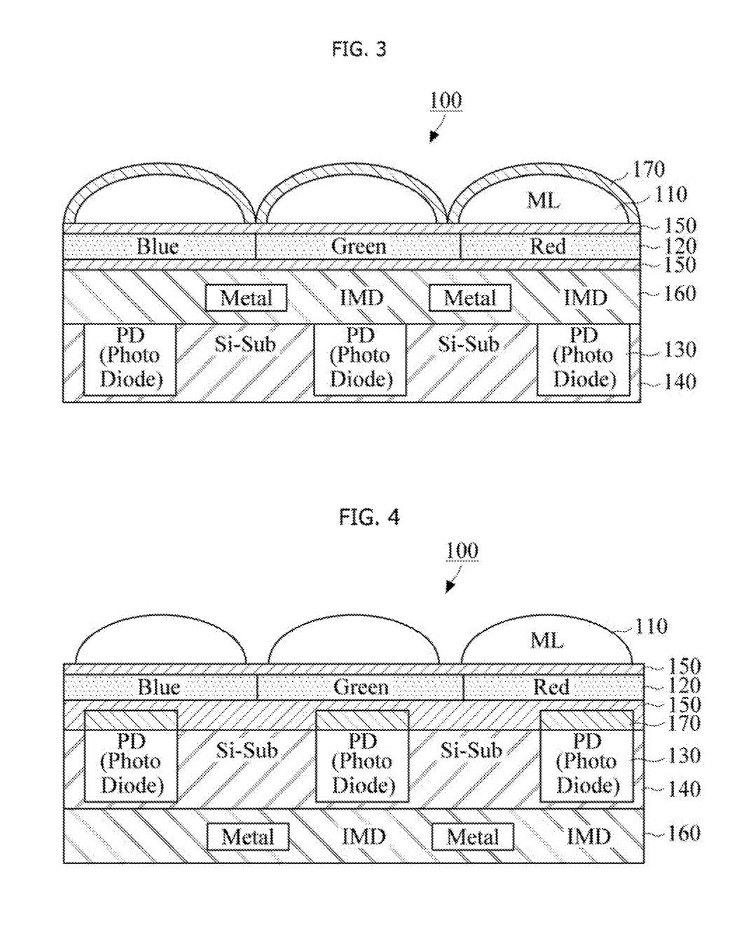

FIG. 3 is a cross sectional view illustrating an image sensor in accordance with a third embodiment of the present invention, and an antireflection film is formed on a side of an optical film of an image sensor of a front side illumination type.

FIG. 4 is a cross sectional view illustrating an image sensor in accordance with a fourth embodiment of the present invention, and an antireflection film is formed on a side of a photodiode of an image sensor of a back side illumination type.

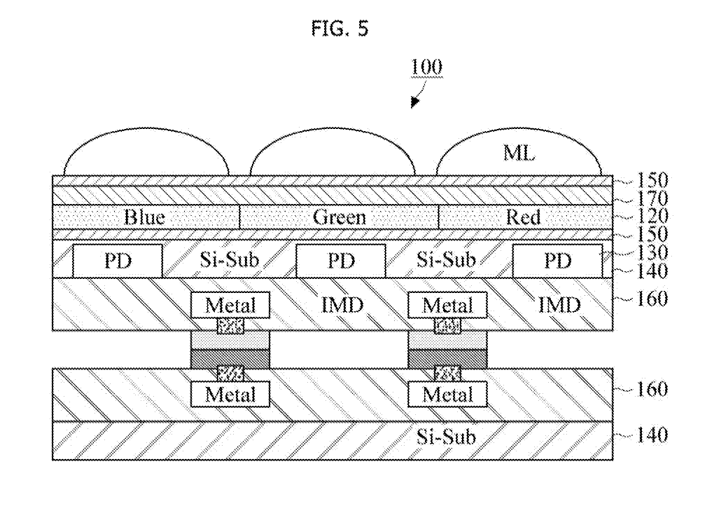

FIG. 5 is a cross sectional view illustrating an image sensor in accordance with a fifth embodiment of the present invention, and an antireflection film is formed on a side of an optical film of an image sensor of a 3-dimensional (3D) stack type.

As shown in drawings, an image sensor chip 100 includes a micro-lens 110, an optical filter 120, a photodiode 130, a semiconductor substrate 140, an over coating layer (OCL) 150, an insulation layer 160 and an antireflection film 170.

As shown in FIGS. 1 to 3, in a case of the image sensor chip of the front side illumination type, the micro-lens 110, the optical filter 120 and the insulation layer 160 are formed on a side of the semiconductor substrate 140, and a light is received from a front side through the micro-lens 110 for receiving the light and the insulation layer 160 having a metal (circuit) on a side of the optical filter 120.

As shown in FIG. 4, in a case of the image sensor chip of the back side illumination type, the light is received from the back side by forming the optical filter 120 and the micro-lens 110 on a side of the semiconductor substrate 140, and forming the insulation layer 160 having the metal (including a driving circuit region) on the other side of the semiconductor device.

As shown in FIG. 5, in a case of the image sensor chip of the 3D stack type, an optical integrated portion and a driving circuit are separated from each other by forming the micro-lens 110 and the optical filter 120 on one semiconductor substrate 140, and forming the insulation layer 160 having the metal on another semiconductor substrate 140.

The micro-lens 110 concentrates the light.

The optical filter 120 passes a specific frequency band of the light which is concentrated by the micro-lens. For example, the optical filter 120 may be a RGB filter that passes a red color, a green color and a blue color.

The photodiode 130 converts the light signal which is passed through the optical filter 120 into an electrical signal.

The photodiode 130 is moduled in the semiconductor substrate 140. For example, the semiconductor substrate 140 may be a silicon (Si) substrate.

A process margin of the micro-lens 110 is acquired by stacking the over coating layer (OCL) 150 on both sides of the optical filter 120 and reducing a process step.

The insulation layer 160 includes a metal (including a driving circuit region), and an inter-metal dielectric is formed in the insulation layer 160. The electrical signal into which the light is converted by the photodiode 130 is applied and processed to the metal included in the insulation layer 160.

The antireflection film 170 is coated on at least one side of the photodiode 130, the optical filter 120 or the micro-lens 110, and suppresses a light reflection.

When the light which is incident on the image sensor chip 100 is reflected by each layer of the image sensor chip 100, a light loss occurs, and an image degradation occurs due to a ghost phenomenon and a flare phenomenon caused by the reflected light.

Because a region where most reflection occurs in the image sensor chip is the photodiode 130, the optical filter 120 and the micro-lens 110, the efficiency such as sensitivity/quantum efficiency (QE) and the like may be improved by forming the antireflection film on the region from which most reflection occurs in the image sensor chip, and the image degradation may be additionally improved by preventing the ghost phenomenon and the flare phenomenon.

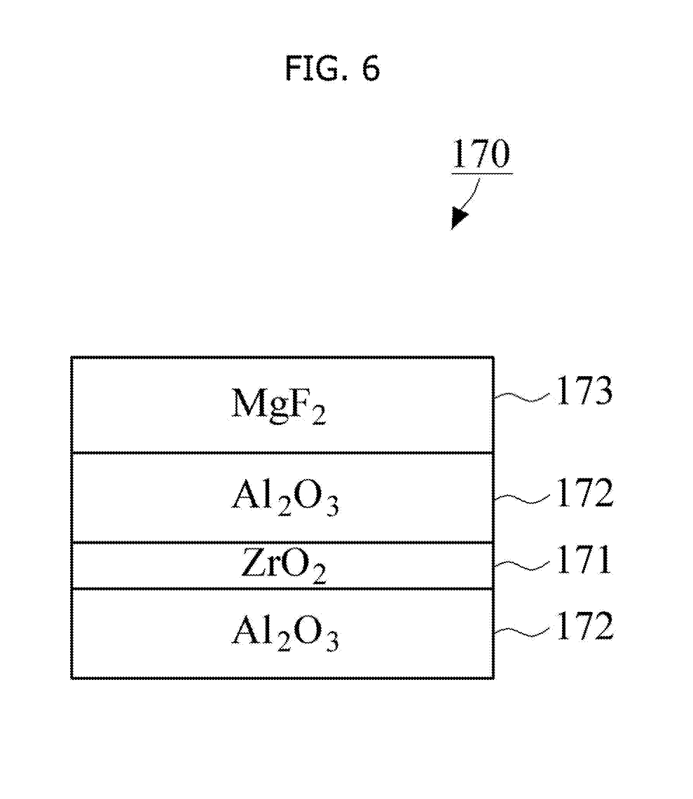

FIG. 6 is a cross sectional view illustrating an antireflection film of an image sensor in accordance with an embodiment of the present invention. The antireflection film 170 may be formed with a multi-coating in a multi-layer. For example, as shown in FIG. 6, the antireflection film 170 may be implemented to include a zirconium oxide (ZrO₂) layer 171 having a refractive index of 2.057 and two aluminum oxide (Al₂O₃) layers having a refractive index of 1.65, which are coating on both sides of the zirconium oxide (ZrO₂) layer.

Meanwhile, the antireflection film 170 may be implemented to further include a magnesium fluoride (MgF₂) layer 173 having a refractive index of 1.25, which is coated on any one of the two aluminum oxide (Al₂O₃) layers 172.

Herein, the zirconium oxide (ZrO₂) layer 171 may be implemented to be coated with the thickness of 160 to 200 Å, and the two aluminum oxide (Al₂O₃) layers 171 may be implemented to be coated with the thickness of 800 to 1000 Å. The magnesium fluoride (MgF₂) layer 173 may be implemented to be coated with the thickness of 1000 to 1300 Å.

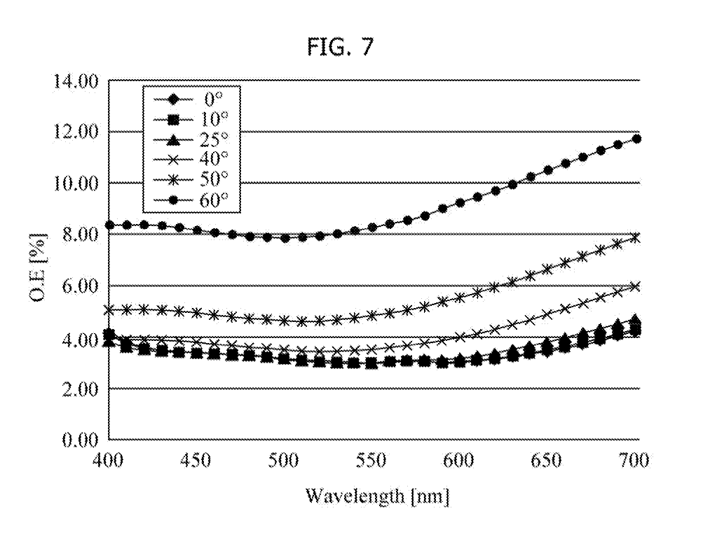

FIG. 7 is a graph illustrating reflectance according to a light incident angle of an image sensor chip in accordance with an embodiment of the present invention. The image sensor chip in accordance with the embodiment of the present invention has a low reflectivity in a section having a light incident angle of 0-60° in a visible ray region of 400-700 nm wavelength, and has a very low reflectivity in a section having a light incident angle of 0-25°.

As described above, the present invention may improve the efficiency such as sensitivity/quantum efficiency (QE) and the like by forming an antireflection film on a layer from which most reflection occurs in the image sensor chip, and additionally improve an image degradation by preventing a ghost phenomenon and a flare phenomenon.

Although various embodiments have been described for illustrative purposes, it will be apparent to those skilled in the art that various changes and modifications may be made without departing from the spirit and scope of the invention as defined in the following claims.

1. An image sensor chip, comprising:
a micro-lens configured to concentrate a light; an optical filter configured to pass a specific frequency band of the light concentrated by the micro-lens;
a photo-diode configured to convert the light, which is passed through the optical filter, into an electrical signal;
a semiconductor substrate in which the photodiode is moduled;
an over coating layer (OCL) configured to be stacked on both sides of the optical filter and obtain a process margin of the micro-lens by reducing a process step;
an insulation layer for an inter-metal dielectric; and
an antireflection film configured to suppress a light reflection on a side of at least one of the photodiode, the optical filter and the micro-lens.

2. The image sensor chip of claim 1, wherein the antireflection film is formed to have a multi-coating layer.

3. The image sensor chip of claim 2, wherein the antireflection film comprises a zirconium oxide layer and two aluminium oxide layers, which are coated on both sides of the zirconium oxide layer.

4. The image sensor chip of claim 3, wherein the antireflection film further comprises a magnesium fluoride layer, which is coated on any one of the two aluminum oxide layers.

5. The image sensor chip of claim 3, wherein the zirconium oxide layer is coated with a thickness of 160 to 200 Å.

6. The image sensor chip of claim 3, wherein the aluminium oxide layer is coated with a thickness of 800 to 1000 Å.

7. The image sensor chip of claim 4, wherein the magnesium fluoride layer is coated with a thickness of 1000 to 1300 Å.

8. The image sensor chip of claim 1, wherein the image sensor chip is a front side illumination type image sensor.

9. The image sensor chip of claim 1, wherein the image sensor chip is a back side illumination type image sensor.

10. The image sensor chip of claim 1, wherein the image sensor chip is a 3-dimensional stack type image sensor.
